(19) United States
(12) Patent Application Publication
(10) Pub. No.: US 2025/0201625 A1
(43) Pub. Date: Jun. 19, 2025

(54) METHOD FOR TRANSFERRING A THIN FILM ONTO A SUPPORT SUBSTRATE

(71) Applicants: Soitec, BERNIN (FR); Commissariat à l'Energie Atomique et aux Énergies Alternatives, Paris (FR)

(72) Inventors: Franck Colas, BERNIN (FR); Marcel Broekaart, BERNIN (FR); Nadia Ben Mohamed, BERNIN (FR); Frédéric Mazen, Grenoble Cedex 09 (FR); Didier Landru, BERNIN (FR); Pablo Acosta Alba, Grenoble Cedex 09 (FR); Oleg Kononchuk, BERNIN (FR); Vincent Larrey, Grenoble Cedex 09 (FR)

(21) Appl. No.: 18/837,443

(22) PCT Filed: Dec. 19, 2022
(86) PCT No.: PCT/EP2022/086746

§ 371 Date: Feb. 11, 2025

(30) Foreign Application Priority Data
Feb. 14, 2022 (FR) FR2201259

(51) Int. Cl. H01L 21/762; H01L 21/18

(52) U.S. Cl. CPC H01L 21/76254; H01L 21/187

(57) ABSTRACT

The invention relates to a method for transferring a thin film onto a support substrate, which comprises: providing a bonded assembly that comprises a donor substrate and the support substrate, assembled by direct bonding at their respective front faces, following a bonding interface, the bonded assembly having a local unbonded area within this bonding interface, the donor substrate further comprising a buried brittle plane; separating along the buried brittle plane, initiated at the local unbonded area after microcrack growth in said plane by thermal activation, the separation resulting in the transfer of a thin film from the donor substrate to the support substrate. The method is characterised in that the local unbonded area is generated solely by a roughened area, produced deliberately on at least one of the front faces of the donor and support substrates prior to assembly, free of topology and having a predetermined roughness with an amplitude of between 0.5 nm RMS and 60.0 nm RMS.

### FIELD OF THE INVENTION

The present invention relates to the field of microelectronics and semiconductors. In particular, the invention relates to a method for transferring a thin film onto a support substrate, based on the Smart Cut™ technology, the thin film exhibiting improved roughness after separation. In particular, the transfer method can be used to manufacture an SOI structure.

### TECHNOLOGICAL BACKGROUND OF THE INVENTION

The Smart Cut™ technology is well known for manufacturing SOI (silicon-on-insulator) structures and, more generally, for thin-film transfer. This technology is based on the formation of a buried brittle plane in a donor substrate, by implanting light species in said substrate; the buried brittle plane delimits, together with a front face of the donor substrate, the thin film to be transferred. The donor substrate and a support substrate are then joined at their respective front faces to form a bonded assembly. The assembly is advantageously carried out by direct bonding, by molecular adhesion, that is, without involving any adhesive material: a bonding interface is thus established between the two assembled substrates. Microcrack growth in the buried brittle plane, through thermal activation, can lead to spontaneous separation along said plane, resulting in the transfer of the thin film onto the support substrate (forming the stacked structure). The remaining donor substrate can be reused for subsequent film transfer. After separation, finishing treatments are typically applied to the stacked structure to restore the crystalline quality and surface roughness of the transferred thin film. In particular, these finishing steps may involve oxidizing or smoothing heat treatments (in a neutral or reducing atmosphere), chemical cleaning and/or etching and/or chemical-mechanical polishing steps, as is known to person skilled in the art. Finally, various tools for inspecting the final structure enable the entire surface of the thin film to be checked.

When separation in the buried brittle plane is spontaneous, significant variability is observed in terms of the surface roughness of the transferred thin film, both at high frequencies (microroughness) and at low frequencies (undulations, local areas of high roughness, mottling, etc.). These variabilities are visible and measurable in particular via the aforementioned inspection tools, when checking the thin film in the final structure.

It should be recalled that the surface roughness of the thin film after finishing can be imaged by mapping obtained using a Surfscan™ inspection tool from KLA-Tencor ([FIG. 1]). The level of roughness and potential patterns (mottling (M), dense areas (ZD), etc.) are measured or made apparent by measuring the diffuse background noise (“haze”) corresponding to the intensity of the light scattered by the surface of the thin film. The haze signal varies linearly with the square of the RMS surface roughness (root-mean-square roughness) in the spatial frequency range from 0.1 μm⁻¹ to 10 μm⁻¹. Please refer to the article “Seeing through the haze” by F. Holsteyns (Yield Management Solution, Spring 2004, pp. 50-54) for more information on this large-area roughness inspection and evaluation technique.

The maps in [FIG. 1] show the surface roughness of two thin films transferred from two bonded assemblies and treated identically up to the finishing. Map (A) shows a peripheral area of residual roughness, known as the “dense area (ZD)” (in particular, at the top of the map); map (B) is completely devoid of this area. More pronounced mottling (M) is also apparent on map (A). The average and maximum roughnesses (expressed in ppm haze) are further significantly different between the two maps (A) and (B). [FIG. 1] shows the variability of the final quality and roughness of the thin films, which is mainly due to the variability of surface roughness (high and low frequencies) after separation.

To improve the quality of the thin films in the final stacked structure, it remains important to reduce the surface roughness (whatever the spatial frequency) of these layers after transfer.

It is known from US2010/330779 to form a local unbonded area at the bonding interface, bordered by a bonded region, to constitute a separation trigger and thus limit the roughness of a thin silicon layer transferred onto a glass support substrate. The local unbonded area is obtained by creating a topology corresponding to a cavity and/or dome (or peak) on the face of the donor substrate (silicon) or support substrate (glass) to be bonded. Cavities and/or peaks of the order of 2 to 3 micrometers are formed on the glass substrate, to create an unbonded area of several tens of mm².

### OBJECT OF THE INVENTION

The present invention proposes a transfer method using a particular fracture initiation point, enabling improved surface roughness of the thin film after separation, to achieve excellent surface quality after the finishing steps of the stacked structure. The method is particularly advantageous for the manufacture of SOI structures.

### BRIEF DESCRIPTION OF THE INVENTION

The present invention relates to a method for transferring a thin film to a support substrate, comprising:
providing a bonded assembly that comprises a donor substrate and the support substrate, assembled by direct bonding at their respective front faces, following a bonding interface, the bonded assembly having a local unbonded area within this bonding interface, the donor substrate further comprising a buried brittle plane,
separating along the buried brittle plane, initiated at the local unbonded area after microcrack growth in said plane by thermal activation, the separation resulting in the transfer of a thin film from the donor substrate to the support substrate.

The method is characterized in that the local unbonded area is generated solely by a roughened area, produced deliberately on at least one of the front faces of the donor and support substrates prior to assembly, said roughened area being free of topology and having a predetermined roughness with an amplitude of between 0.5 nm RMS excluded, and 60.0 nm RMS excluded.

According to advantageous features of the invention, taken alone or in any feasible combination:
the roughened area is produced by at least one laser shot generating only a surface fusion, within the first 1 to 30 nanometers, of a material making up the donor substrate and/or the support substrate, on the side of their respective front faces,
the laser shot has a pulse duration of between 1 ns and 1000 ns, preferentially between 10 ns and 500 ns.
the laser shot is performed with a laser of wavelength 308 nm, and with an energy density of between 1.8 J/cm² and 2.5 J/cm²;
a laser shot irradiates a circular surface with a diameter of less than 200 micrometers;
the roughened area is produced by a plurality of laser shots, for example between two and fifteen laser shots, the adjacent circular surfaces irradiated by successive laser shots being tangential or having an overlap percentage of between 1% and 95%;
the front face, whereupon the roughened area is formed, is made of monocrystalline silicon, and the predetermined roughness has an amplitude between 0.5 nm RMS and 4.0 nm RMS, preferentially between 1.0 nm RMS and 2.5 nm RMS;
the front face, whereupon the roughened area is formed, is made of polycrystalline silicon, and the predetermined roughness has an amplitude between 0.5 nm RMS and 5.0 nm RMS, preferentially between 2.0 nm RMS and 5.0 nm RMS;
the front face, whereupon the roughened area is formed, is made of silicon oxide, and the predetermined roughness has an amplitude of between 1.0 nm RMS and 60.0 nm RMS;
the roughened area is formed on the front face of the donor substrate, before the formation of the buried brittle plane in said donor substrate;
the donor substrate is formed from a first material on its front face, and a preliminary roughened area is formed on the surface of said material, and thermal oxidation of the first material of the donor substrate is carried out after formation of the preliminary roughened area and before formation of the buried brittle plane, to form an insulating layer that will be assembled on the support substrate in the bonded assembly, said insulating layer comprising, on its free face, the roughened area plumb with the preliminary roughened area;
the support substrate is formed from a first material on its front face, and a preliminary roughened area is formed on the surface of said material, and thermal oxidation of the first material of the support substrate is carried out after formation of the preliminary roughened area, to form an insulating layer that will be assembled on the donor substrate in the bonded assembly, said insulating layer comprising, on its free face, the roughened area plumb with the preliminary roughened area;
the local unbonded area has a shape, in the plane of the bonding interface, whereof at least a portion of the contour has a radius of curvature smaller than the radius of a circular bonding defect of the same area;
the local unbonded area has at least one lateral dimension, in the plane of the bonding interface, of less than 300 micrometers;
the local unbonded area is located in a central region of the bonded assembly, in the plane of the bonding interface;
the buried brittle plane is formed in the donor substrate by implanting light species such as hydrogen, helium or a combination of both species;
the donor substrate and/or the support substrate have an insulating layer at least on their respective front side, which forms a buried insulating layer adjacent to the bonding interface in the bonded assembly;
the thin film from the donor substrate is monocrystalline silicon and the support substrate comprises monocrystalline silicon, to form a stacked SOI structure.

### BRIEF DESCRIPTION OF THE DRAWINGS

Other features and advantages of the invention will emerge from the following detailed description of the invention with reference to the appended figures, in which:

FIG. 1 shows two representative surface roughness maps of two transferred thin films, from two bonded assemblies processed identically until finishing, using a conventional method; both maps were obtained via a Surfscan™ inspection tool;

FIG. 2 shows a graph indicating the surface roughness of the thin films, based on the fracture time, for a plurality of bonded assemblies (different from the bonded assemblies shown in reference to FIG. 1) treated in an identical manner until finishing, according to a conventional method;

FIG. 3a shows a bonded assembly involved in an intermediate step of the transfer method according to the invention;

FIG. 3b shows an example of a donor or support substrate comprising a roughened area deliberately formed on its front face, in accordance with the transfer method of the invention, which roughened area has a predetermined roughness;

FIG. 4 shows a stacked structure and the remainder of a donor substrate, obtained by a transfer method in accordance with the invention;

FIG. 5 shows the evolution of the RMS (root-mean-square) and PV (peak-to-valley) roughness of a silicon surface irradiated by a laser shot, based on laser energy density;

FIG. 6 shows two representative maps of the surface roughness (after finishing) of two transferred thin films for a first and a second RFSOI structure, the first (110) having been obtained with a transfer method in accordance with the invention, the second (110′) with a conventional transfer method; both maps were obtained via a Surfscan™ inspection tool

FIG. 7 shows various examples of shapes of the roughened area and the associated local unbonded area, implemented in the transfer method in accordance with the invention;

FIGS. 8a and 8b show images of a non-transferred area corresponding to the local unbonded area of a bonded assembly, the non-transferred area being observed on a stacked structure obtained by a transfer method according to the invention.

Some figures are schematic depictions which, for the sake of readability, are not to scale. In particular, the thicknesses of the layers along the z axis are not to scale with respect to the lateral dimensions along the x and y axes.

The same references in the figures and in the description may be used for elements of the same type.

### DETAILED DESCRIPTION OF THE INVENTION

The invention relates to a method for the transfer of a thin film onto a support substrate, to form a stacked structure. As mentioned in the introduction, such a stacked structure can be of the SOI type, comprising a thin silicon surface layer, an intermediate insulating layer of silicon oxide and a silicon support substrate. The support substrate can optionally comprise other functional layers, such as a charge trapping layer, for example for SOI structures designed for radio frequency (RF) applications. The transfer method according to the invention is not limited to the manufacture of SOI, however, and can be applied to many other stacked structures in the field of microelectronics, microsystems and semiconductors.

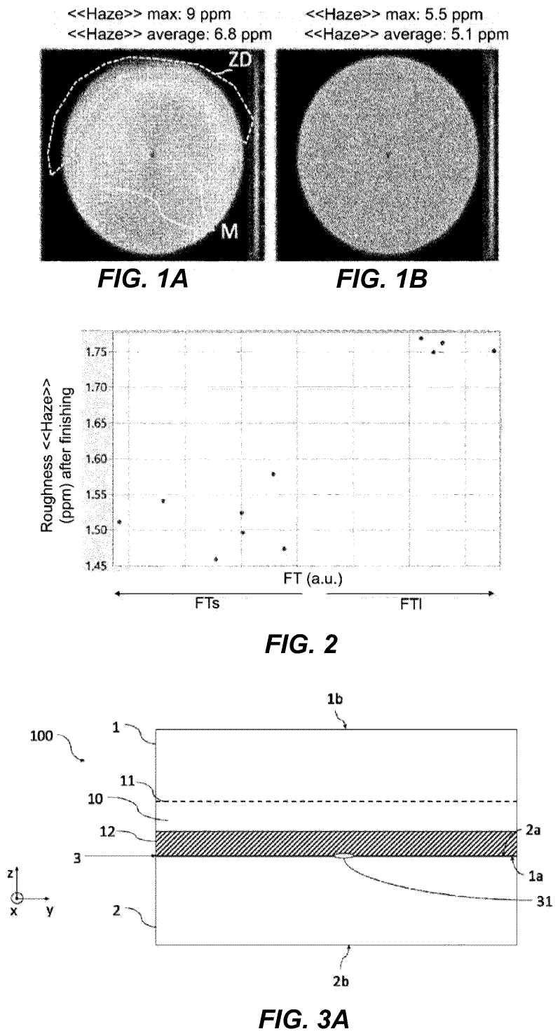

The transfer method according to the invention is based on Smart Cut™ technology. When separation in the buried brittle plane is spontaneous, the fracture time (that is, the time after which separation occurs, during thermal fracture annealing) may differ between a plurality of identically treated bonded assemblies, undergoing the same annealing, in the same oven. The fracture time (FT) depends on a multitude of parameters, linked to the formation of the buried brittle plane, the fracture annealing, the nature of the bonded assembly, etc. The applicant has noted that, for bonded assemblies prepared in a similar way and undergoing the same fracture annealing, separations occurring at short fracture times (FTs) give rise to lower high-frequency surface roughness (microroughness) of thin films in the final stacked structures (that is, after transfer and finishing) than separations occurring at longer fracture times (FT1), as can be seen in [FIG. 2]. Additionally, long fracture times induce a local area of very high roughness (called the dense area ZD) at the edge of the thin film after fracture, which occurs little or not at all when the fracture time is short. This dense area degrades the quality and roughness of the thin film, even after finishing, as can be seen on map (A) in [FIG. 1].

The transfer method according to the invention therefore aims to initiate spontaneous separation in the buried brittle plane in an early (short fracture time) and repeatable (low fracture time dispersion between a plurality of similar bonded assemblies) manner, so as to substantially improve the surface roughness of the transferred thin film.

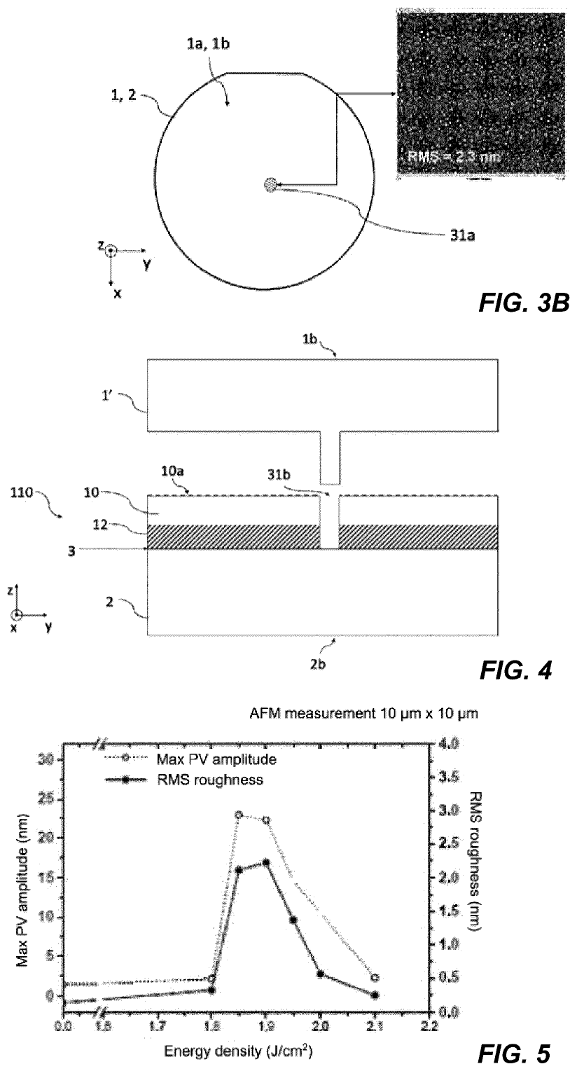

To achieve this, the transfer process first comprises providing a bonded assembly 100 comprising a donor substrate 1 and the support substrate 2, assembled by direct bonding at their respective front faces (1a, 2a), along a bonding interface 3 ([FIG. 3a]).

The donor substrate 1 is preferentially in the form of a wafer with a diameter of 100 mm, 150 mm, 200 mm, 300 mm or even 450 mm, and with a thickness typically between 300 μm and 1 mm. It comprises a front face 1a and a rear face 1b. The surface roughness of the front face 1a is chosen to be less than 1.0 nm RMS, preferentially even less than 0.5 nm RMS (measured by atomic force microscopy (AFM), for example on a 20 μm×20 μm scan). The donor substrate 1 can be made of silicon or any other semiconducting or insulating material for which thin-film transfer may be of interest (e.g. SiC, GaN, III-V compounds, piezoelectric materials, etc.). It should also be noted that the donor substrate 1 may comprise one or more additional layers 12, at least on its front side 1a, such as an insulating layer. As shown in [FIG. 3a], this additional layer 12 becomes a buried intermediate layer in the bonded assembly 100, after assembly of the donor substrate 1 and the support substrate 2.

The donor substrate 1 comprises a buried brittle plane 11, which delimits a thin film 10 to be transferred. As is well known referring to the Smart Cut™ technology, such a buried brittle plane 11 can be formed by implanting light species, such as hydrogen, helium or a combination of both. The light species are implanted at a determined depth in the donor substrate 1, consistent with the thickness of the targeted thin film 10. These light species will form, around the determined depth, microcavities distributed in a thin film substantially parallel to the front face 1a of the donor substrate 1, or parallel to the plane (x, y) in the figures. This thin film is called the buried brittle plane 11, for simplicity's sake.

The implantation energy of the light species is chosen so as to reach the determined depth. For example, hydrogen ions will be implanted at an energy of between 10 keV and 210 keV, and at a dose of between 5E16/cm² and 1E17/cm², to delimit a thin film 10 having a thickness of the order of 100 nm to 1500 nm. It should be recalled that an additional layer may be deposited on the front face 1a of the donor substrate 1, prior to the ion implantation step. This additional layer may be composed of a material such as silicon oxide or silicon nitride, for example. It can be retained for the next assembly step (and form all or part of the intermediate layer of the bonded assembly 100), or it can be removed.

The support substrate 2 is also preferentially in the form of a wafer with a diameter of 100 mm, 150 mm, 200 mm, 300 mm or even 450 mm, and with a thickness typically between 300 μm and 1 mm. It has a front face 2a and a rear face 2b. The surface roughness of the front face 2a is chosen to be less than 1.0 nm RMS, or preferentially even less than 0.5 nm RMS (measured by AFM, for example on a 20 μm×20 μm scan). The support substrate 2 can be made of silicon or any other semiconducting or insulating material for which thin-film transfer may be of interest (e.g. SiC, GaN, III-V compounds, piezoelectric materials, insulating materials, etc.). It should also be noted that the support substrate 2 may comprise one or more additional layers, at least on its front side 2a, such as an insulating layer and/or a charge trapping layer. This (or these) additional layer(s) is (are) buried in the bonded assembly 100, after assembly of the donor substrate 1 and the support substrate 2.

Assembly between the donor substrate 1 and the support substrate 2 is based on direct bonding by molecular adhesion. As is well known per se, such bonding does not require an adhesive material, as atomic-scale bonds are established between the joined surfaces, forming the bonding interface 3. Several types of molecular adhesion bonding exist, which differ in particular by their temperature, pressure, atmosphere conditions or treatments prior to contacting the surfaces. Mention may be made of bonding at room temperature with or without prior plasma activation of the surfaces to be assembled, atomic diffusion bonding (ADB), surface-activated bonding (SAB), etc.

The assembly step may comprise, before the contacting of the front faces 1a, 2a to be assembled, conventional chemical cleaning sequences (for example, RCA cleaning), surface activation (for example, oxygen or nitrogen plasma) or other surface preparations (such as cleaning by scrubbing), capable of promoting the quality of the bonding interface 3 (few defects, strong adhesion energy).

The bonded assembly 100 according to the invention has the particularity of comprising a local unbonded area 31 within the bonding interface 3 ([FIG. 3a]). In other words, this local unbonded area 31 is bordered by the bonding interface 3, which is closed, reflecting the molecular adhesion forces uniting the front faces 1a, 2a of the assembled substrates 1, 2.

The local unbonded area 31 is generated solely by the presence of a roughened area 31a, deliberately created on at least one of the front faces 1a, 2a of the donor 1 and support 2 substrates, prior to their assembly ([FIG. 3b]). The roughened area 31a is free of any low-frequency topology or ripple, that is, with a typical wavelength greater than 100 nm. It has a predetermined high-frequency roughness, which is greater than the roughness of the front faces 1a, 2a around this roughened area 31a. The roughness of the front faces 1a, 2a can typically vary based on the nature of the materials of said faces 1a, 2a and based on the type of direct bonding implemented, but it always enables a bonded (closed) interface to be obtained, whereas the predetermined roughness in the roughened area 31a prevents local bonding between the two faces 1a, 2a.

The amplitude of the predetermined roughness is strictly greater than 0.5 nm RMS and strictly less than 60.0 nm RMS, with typical wavelengths between 10 nm and 100 nm (corresponding to high-frequency microroughness). As is well known, the term RMS (“root mean square”) corresponds to a root-mean-square roughness value. The technique used to measure this microroughness is atomic force microscopy (AFM), on scans from 10×10 μm² to 30×30 μm². It should be recalled that the roughened area 31a does not have a topology that would correspond to a low-frequency ripple, but only a microroughness in the spatial frequency range stated above. The maximum peak-to-valley (PV) amplitude in the roughened area 31a is typically between 5.0 nm and 300.0 nm, preferentially between 5.0 nm and 60.0 nm.

In particular, in the example shown in [FIG. 3b], the roughened area 31a has a roughness of 2.3 nm RMS and 25 nm PV, measured by AFM on a 10 μm×10 μm scan (image on the right in [FIG. 3b]).

According to a particular embodiment used in particular for the manufacture of SOI structures, the front face 1a, 2a, whereupon the roughened area 31a is produced, is made of monocrystalline silicon, and the predetermined roughness preferentially has an amplitude of between 0.5 nm RMS and 4.0 nm RMS (typically, 5.0 nm PV to 40.0 nm PV). Even more preferentially, this amplitude is between 1.0 nm RMS and 2.5 nm RMS (typically 10.0 nm PV to 25.0 nm PV), or even between 1.5 nm RMS and 2.5 nm RMS.

In another advantageous embodiment, the front face 1a, 2a of the substrate 1, 2, whereupon the roughened area 31a is formed, is made of polycrystalline silicon, and the predetermined roughness has an amplitude between 0.5 nm RMS and 5.0 nm RMS (typically, 5.0 nm PV to 60.0 nm PV).

Even more preferentially, this amplitude is between 2.0 nm RMS and 5.0 nm RMS (typically 20.0 nm PV to 60.0 nm PV). This embodiment is particularly useful for manufacturing SOI structures suitable for RF applications, where the front face 2a of the support substrate 2 comprises a polycrystalline silicon charge trapping layer.

According to yet another embodiment, the front face 1a, 2a, whereupon the roughened area 31a is formed, is made of silicon oxide, and the predetermined roughness has an amplitude of between 1.0 nm RMS and 60.0 nm RMS.

Note that, when the front face 1a of the donor substrate 1 carries the roughened area 31a, the latter is preferentially produced before the formation of the buried brittle plane 11 in said substrate 1, to limit any damage or premature ripening of the microcavities composing it.

It is also possible to create a preliminary roughened area on a first material forming the donor substrate 1, on its front face; for example, the first material could be silicon. The first material of the donor substrate 1 is then thermally oxidized to form an insulating layer (e.g. silicon oxide). The thickness of the insulating layer may, for example, be less than or equal to 200 nm. Said insulating layer (corresponding to the additional layer 12 shown in [FIG. 3a]) comprises, on its free face (the front face 1a of the donor substrate 1), the roughened area 31a plumb with the preliminary roughened area developed in the first material. In fact, oxidation preserves at least part of the high-frequency roughness of the first material in the preliminary roughened area: the aim is to form a microroughness in the preliminary roughened area capable of giving rise to a predetermined roughness of the roughened area 31a after oxidation, in the aforementioned range of amplitudes. After formation of the buried brittle plane 11 in the donor substrate 1, the insulating layer 12 is assembled on the support substrate 2 in the bonded assembly 100, and the roughened area 31a generates the local unbonded area 31 within the bonding interface 3. In this case, the roughened area 31a on the front face 1a of the donor substrate 1 has not been produced directly by “roughening” the insulating layer 12, but is derived from a preliminary roughened area present in an underlying material.

Although the formation of this preliminary roughened area has been disclosed with reference to the donor substrate 1, it could of course be applied to the support substrate 2.

Once the bonded assembly 100 has been formed and comprises the local unbonded area 31 within its bonding interface 3, the transfer method according to the invention involves applying thermal annealing to it, which will give rise to spontaneous separation along the buried brittle plane 11. Separation leads to the transfer of the thin film 10 from the donor substrate 1 to the support substrate 2, to form the stacked structure 110 ([FIG. 4]). A non-transferred area 31b, to which the thin film 10 has not been transferred, is present plumb with the location of the local unbonded area 31. The remainder of the donor substrate 1′ is also obtained.

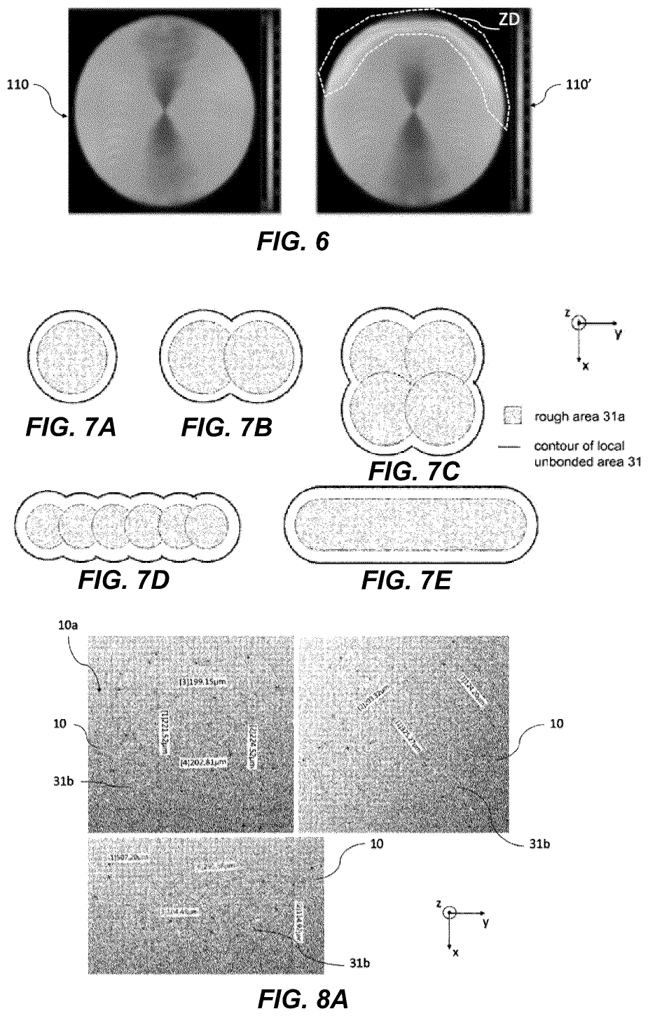

The local unbonded area 31 acts as a fracture initiation point, in the buried brittle plane 11 and at or proximate to said area 31, after microcrack growth in the buried brittle plane 11 by thermal activation. This fracture initiation occurs earlier than with a bonded assembly 100 that does not comprise the local unbonded area 31: this gives access to short fracture times, which provide low surface roughness, after transfer, on the face 10a of the thin film 10. Examples, detailed below, show a clear improvement in surface roughness after transfer, due to the short fracture times obtained owing to the local unbonded area 31, which acts as a fracture initiation point ([FIG. 6], stacked structure 110).

The local unbonded area 31 according to the invention differs from the prior art in that it is due solely to the presence of a roughened area 31a on the front face 1a, 2a of one or other of the donor substrate 1 and support substrate 2. No low-frequency topology is involved (bumps, holes, cavities, particles). The internal volume of the local unbonded area 31 thus created is extremely small; in fact, the accumulation, in this internal volume, of various gases resulting in particular from the vaporization of the water monolayers present on the bonded faces 1a, 2a or from the exo-diffusion of light species by the front face 1a of the donor substrate 1 enables rapid pressurization favorable to fracture initiation as soon as the level of ripening of the microcracks in the buried brittle plane 11 allows it.

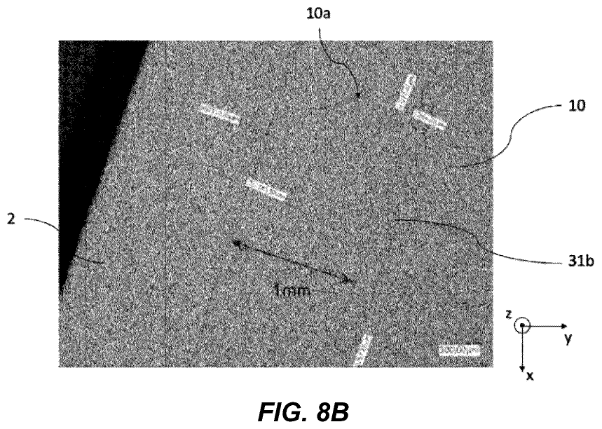

The local unbonded area 31 can be located at various positions in the plane of the bonding interface 3: in particular, in a central region of the bonded assembly 100 or in a peripheral region or even in an intermediate region between these two extremes. In the peripheral region, it is preferable for the local unbonded area 31 to be at least 1 mm from the peripheral (unbonded) crown of the bonded assembly 100. It should be recalled that the unbonded crown (visible in [FIG. 8b]) is due to the presence of a dropped edge and a chamfer at the edge of the assembled substrates 1, 2.

The applicant has observed that positioning the local unbonded area 31 in the center, or in a central region of the bonded assembly 100 (as for example shown in [FIG. 3b]) not only reduces the final roughness (“haze”) of the transferred thin film 10, over its entire surface, but also drastically limits, or even eliminates, the dense area ZD, which corresponds to a local peripheral area of very high roughness ([FIG. 6]).

The local unbonded area 31 can have different shapes, in the plane of the bonding interface 3 (that is, in the (x,y) plane). Some examples are shown in [FIG. 7].

Advantageously, the local unbonded area 31 has a shape, in the (x,y) plane, whereof at least a portion of the contour has a radius of curvature smaller than the radius of a circular bonding defect of the same area (FIGS. 7 (b), (c), (d)). The applicant has demonstrated that a contour with locally small radii of curvature, rectilinear portions or singular points (such as cusps, for example), gives the local unbonded area 31 excellent fracture initiation efficiency: short fracture times with little dispersion between a plurality of identical bonded assemblies can therefore be obtained, giving rise to low, uniform and reproducible surface roughness of thin films 10.

FIGS. 8a and 8b show optical microscope images of non-transferred areas 31b (generated by areas 31) on stacked structures 110 obtained by the transfer method of the invention. These areas 31b have contours with particular shapes as previously mentioned in reference to the increased effectiveness of the local unbonded area 31 as a fracture initiation point.

To avoid penalizing the transfer integrity of the thin film 10, the local unbonded area 31 advantageously has at least one lateral dimension, in the (x,y) plane, of less than 300 micrometers. This is typically achieved by forming a roughened area 31a, on one of the front faces 1a, 2a of the substrates 1, 2, with an associated lateral dimension less than or equal to 200 micrometers.

The roughened area 31a can be produced by various techniques, including chemical, wet or dry etching, after protecting the concerned front face 1a, 2a, with the exception of the area to be roughened.

Nevertheless, it is advantageous to form this roughened area with as little contact as possible with the rest of the concerned front face 1a, 2a, so as to reduce the risk of contamination or degradation (scratches, etc.) of this face, which is to be assembled.

A particularly advantageous technique for forming the roughened area 31a consists in using a laser shot, capable of generating only a surface melting of the material of the front face 1a, 2a, and only in the area to be roughened. This surface melting typically takes place in the first few nanometers of material on the front face of 1a, 2a, between 1 nm and 30 nm: it therefore involves a melting limit regime and not at all ablation regimes that remove material or hollow it out. The laser shot used here creates no topology, no cavities or bumps, only high-frequency roughness in the RMS and PV ranges mentioned above.

Preferentially, the laser shot is fired over a very short pulse, typically lasting between 1 ns and 1000 ns, and more advantageously between 10 ns and 500 ns. The wavelength of the laser used can be chosen between 100 nm and 550 nm, preferably between 250 nm and 400 nm.

By way of example, when the material is silicon, the laser shot can be performed with a laser of wavelength 308 nm, and with an energy density of between 1.8 J/cm² and 2.5 J/cm². [FIG. 5] shows curves relating the roughness (RMS and PV) of a monocrystalline silicon surface, irradiated by a laser shot (wavelength 308 nm, pulse duration 160 ns), to the energy density of the laser shot. It is important to be in the melting limit regime (in this example, at 1.9+/−0.1 J/cm²), to generate high-frequency roughness of the expected amplitude. This regime corresponds to “discontinuous” melting of the irradiated surface, which means that melted and unmelted areas are induced on the surface, conducive to the formation of the desired high-frequency roughness. If the energy density is too low (<1.8 J/cm²), melting cannot be achieved and little or no roughness is generated; if the energy density is too high (>2 J/cm²), “homogeneous” melting of the entire irradiated surface takes place, with uniform recrystallization and potentially too little roughness.

Note that in the case where the material of the front face 1a, 2a (which will undergo the laser shot) is a silicon oxide and the underlying material is silicon, the laser shot passes through the silicon oxide layer and will generate melting of the silicon, which will induce the formation of wrinkles on the oxide surface. These wrinkles form the expected high-frequency roughness, in the irradiated region, on the front face 1a, 2a.

As already mentioned with regard to a preferential maximum lateral dimension of the local unbonded area 31, the laser beam irradiates a generally circular surface with a diameter advantageously less than 200 micrometers. The roughened area 31a generated after a laser shot is approximately the size of the irradiated surface.

To generate advantageous shapes for the local unbonded area 31, the roughened area 31a can be produced using a plurality of laser shots, for example, two ([FIG. 7] (b)), three, four ([FIG. 7] (c)), five, six ([FIG. 7] (d)) or even fifteen laser shots. To induce a single local unbonded area 31 with a particular shape and not a plurality of circular areas 31, the surfaces irradiated by successive laser shots must at least be tangent; they may also have a certain percentage of overlap (between 1% and 95%, or between 20% and 70%). As shown in FIGS. 7 (b), (c), (d), it is thus possible to form local unbonded area 31 contours favorable to fracture initiation, as they present singular points or small radii of curvature locally; with an overlap of the order of 50%, it is possible to form a roughened area 31a with a capsule shape ([FIG. 7] (e)): a portion of the contour of the local unbonded area 31 thus generated has a straight portion, making it effective for fracture initiation.

The roughened area 31a and local unbonded area 31 shapes mentioned above are of course not exhaustive, and any other geometric or other shape could be envisaged.

### Example Embodiment

In a first example, the transfer method is used to produce an FDSOI (fully depleted SOI) structure, that is, with a thin surface film and a thin buried insulating layer.

The donor substrate 1 is a monocrystalline silicon wafer with a diameter of 300 mm, and comprises a 35 nm-thick insulating layer 12 of silicon oxide on its front face 1a. The buried brittle plane 11 is formed by co-implantation of helium and hydrogen ions at energies of 40 keV and 25 keV, respectively, and at doses of 1E16/cm² and 1E16/cm², respectively.

The support substrate 2 is a monocrystalline silicon wafer with a diameter of 300 mm.

A laser shot is fired at the center of the support substrate 2, on the side of its front face 2a, so as to cause melting/recrystallization of the surface only, in a melting limit regime. The laser conditions are as follows: wavelength 308 nm, laser pulse duration 160 ns, energy density 1.9 J/cm², quasi-circular irradiated surface with radius 65 μm. A laser shot therefore leads to the formation of a roughened area at the irradiated surface, with an RMS roughness of 2.3 nm+/−0.5 nm, measured by AFM on a scan of 10×10 μm² (see, for example, the AFM image in [FIG. 3b]).

A conventional surface preparation (cleaning, plasma activation) of the two substrates 1, 2 is then carried out with a view to molecular adhesion bonding.

Assembly, based on direct contact between the front faces 1a, 2a of the donor substrate 1 and the support substrate 2, produces a bonded assembly 100. The bonded assembly 100 comprises a local unbonded area 31 plumb with the roughened area 31a (at the center of the bonded assembly 100), within the bonding interface 3. The local unbonded area 31 has a diameter of around 130 to 250 μm.

Fracture annealing, carried out in a horizontal furnace (suitable for treating a plurality of bonded assemblies 100 collectively), is applied at between 200° C. and 400° C.

The local unbonded area 31 enables fracture to be initiated along the buried brittle plane 11 in a short time, that is, around 25% of the average fracture time in the absence of the local unbonded area 31, in the case of isothermal annealing. By considering a plurality of collectively treated bonded assemblies 100, the local unbonded area 31 further makes it possible to obtain less dispersed fracture times.

The SOI structure 110 obtained after separation has a non-transferred area 31b in place of the local unbonded area 31 of the bonded assembly 100, and whose size is substantially the same as that of said area 31.

The surface quality 10a of the transferred thin film 10 is improved compared with an SOI 110′ structure obtained from a conventional bonded assembly, without a local unbonded area 31. This is particularly visible after the application of finishing steps (mainly oxidation and smoothing heat treatments) to heal the transferred thin film 10 and smooth its surface: SOI structures 110 obtained by the method of the invention do not show dense areas of roughness at the periphery of the thin film 10, unlike certain SOI structures 110′ obtained by a conventional method (without local unbonded areas 31).

In a second example, the transfer method is used to produce an RFSOI (SOI for radio frequency applications) structure, that is, a thin surface film, an insulating layer and a charge trapping layer on the support substrate 2.

The donor substrate 1 is a monocrystalline silicon wafer with a diameter of 300 mm, and comprises a 200 nm-thick insulating layer 12 of silicon oxide on its front face 1a. The buried brittle plane 11 is formed by co-implantation of hydrogen and helium ions at energies of 35 keV and 50 keV, respectively, and at doses of 1.2E16/cm² and 1.1E16/cm², respectively.

The support substrate 2 is a monocrystalline silicon wafer with a diameter of 300 mm. A polycrystalline silicon charge trapping layer, approximately 1 μm thick, is arranged on the front face 2a side of the support substrate 2.

A laser shot is fired into a peripheral region of the support substrate 2, on the side of its front face 2a (therefore on the polycrystalline silicon), so as to cause melting/re-crystallization of the surface only. In particular, the laser shot is fired at a distance of between 3 mm and 10 mm, for example 5 mm, from the edge of the support substrate 2.

The laser conditions are as follows: wavelength 308 nm, laser pulse duration 160 ns, energy density 1.9 J/cm², quasi-circular irradiated surface with radius 65 μm. A laser shot therefore leads to the formation of a roughened area at the irradiated surface, with an RMS roughness of 2.7 nm+/−0.5 nm, measured by AFM on a scan of 10×10 μm².

A conventional surface preparation (cleaning, plasma activation) of the two substrates 1, 2 is then carried out with a view to molecular adhesion bonding.

Assembly, based on direct contact between the front faces 1a, 2a of the donor substrate 1 and the support substrate 2, produces a bonded assembly 100. The bonded assembly 100 comprises a local unbonded area 31 plumb with the roughened area 31a (at the edge of the bonded assembly 100), within the bonding interface 3. The local unbonded area 31 has a diameter of around 130 to 250 μm.

Fracture annealing, carried out in a horizontal furnace (suitable for treating a plurality of bonded assemblies 100 collectively), is applied at between 200° C. and 550° C.

The local unbonded area 31 enables fracture to be initiated along the buried brittle plane 11 in a short time (around 30% of the average fracture time without the local unbonded area 31). By considering a plurality of collectively treated bonded assemblies 100, the local unbonded area 31 further makes it possible to obtain less dispersed fracture times.

The SOI structure 110 obtained after separation has a non-transferred area in place of the local unbonded area 31 of the bonded assembly 100, and whose size is substantially the same as that of said area 31, typically less than 250 μm.

The surface quality 10a of the transferred thin film 10 is improved compared with an SOI 110′ structure obtained from a conventional bonded assembly, without a local unbonded area 31. This is particularly visible after the application of finishing steps (mainly oxidation and smoothing heat treatments) to heal the transferred thin film 10 and smooth its surface: the map in [FIG. 6] of the SOI structure 110 obtained by the method of the invention shows an absence of dense areas of roughness at the periphery of the thin film 10, unlike the SOI structure 110′ obtained by a conventional method (without local unbonded areas 31); it also shows a lower overall level of roughness over the entire surface of the thin film 10 of the SOI structure 110.

In a third example, the transfer method is used to produce an SOI structure, that is, having a thin surface film, an insulating layer and a support substrate 2.

The donor substrate 1 is a monocrystalline silicon wafer with a diameter of 300 mm.

A laser shot is fired into a central or peripheral region of the donor substrate 1, on the side of its front face 1a (therefore on the silicon), so as to cause melting/re-crystallization of the surface only. The laser conditions are as follows: wavelength 308 nm, laser pulse duration 160 ns, energy density 1.9 J/cm², quasi-circular irradiated surface with radius 65 μm. A laser shot therefore leads to the formation of a preliminary roughened area at the irradiated surface, with an RMS roughness of 2.3 nm+/−0.5 nm, measured by AFM on a scan of 10×10 μm².

After standard cleaning of the donor substrate 1, thermal oxidation is carried out, typically in the 900° C.-1050° C. temperature range. After this oxidation, the front face 1a of donor substrate 1 comprises an insulating layer 12 of silicon oxide measuring 100 nm thick. Plumb with the preliminary roughened area, a roughened area 31a is present on the free face 1a of the insulating layer 12. This roughened area 31a has an RMS roughness substantially identical to that of the preliminary roughened area, that is, about 2.2 nm+/−0.5 nm (AFM on 10×10 μm² scan).

The buried brittle plane 11 is formed by co-implantation of hydrogen and helium ions at energies of 35 keV and 50 keV, respectively, and at doses of 1.2E16/cm² and 1.1E16/cm², respectively, through the insulating layer 12, in the donor substrate 1.

The support substrate 2 is a monocrystalline silicon wafer with a diameter of 300 mm.

A conventional surface preparation (cleaning, plasma activation) of the two substrates 1, 2 is then carried out with a view to molecular adhesion bonding.

Assembly, based on direct contact between the front faces 1a, 2a of the donor substrate 1 and the support substrate 2, produces a bonded assembly 100. The bonded assembly 100 comprises a local unbonded area 31 plumb with the roughened area 31a, within the bonding interface 3. The local unbonded area 31 has a diameter of around 100 μm.

Fracture annealing, carried out in a horizontal furnace (suitable for treating a plurality of bonded assemblies 100 collectively), is applied at between 200° C. and 550° C.

The local unbonded area 31 enables fracture to be initiated along the buried brittle plane 11 in a short time (around 30% of the average fracture time without the local unbonded area 31). By considering a plurality of collectively treated bonded assemblies 100, the local unbonded area 31 makes it possible to obtain less dispersed fracture times.

The SOI structure 110 obtained after separation has a non-transferred area in place of the local unbonded area 31 of the bonded assembly 100, and whose size is substantially the same as that of said area 31, typically less than 200 μm.

The surface quality 10a of the transferred thin film 10 is improved compared with an SOI structure 110′ obtained from a conventional bonded assembly, without a local unbonded area 31: it shows an absence of dense area ZD of roughness at the periphery of thin film 10, as well as a lower overall level of roughness over the entire surface of the thin film 10.

In a fourth example, the transfer method is used to produce an RFSOI (SOI for radio frequency applications) structure, that is, a thin surface film, an insulating layer and a charge trapping layer on the support substrate 2.

The donor substrate 1 is a monocrystalline silicon wafer with a diameter of 200 mm, and comprises a 400 nm-thick insulating layer 12 of silicon oxide on its front face 1a. The buried brittle plane 11 is formed by implanting hydrogen ions at an energy of 50 keV, and a dose of 6E16/cm².

The support substrate 2 is a monocrystalline silicon wafer with a diameter of 200 mm. A polycrystalline silicon charge trapping layer, approximately 2 μm thick, is arranged on the front face 2a side of the support substrate 2.

A plurality of laser shots is fired into a peripheral region of the support substrate 2, on the side of its front face 2a (therefore on the polycrystalline silicon), so as to cause melting/re-crystallization of the surface only. In particular, the laser shot is fired at a distance of between 3 mm and 10 mm, for example 5 mm, from the edge of the support substrate 2.

The laser conditions are as follows: wavelength 308 nm, laser pulse duration 160 ns, energy density 2 J/cm², quasi-circular irradiated surface with radius 65 μm, for each laser shot. A succession of eleven aligned laser shots, with approximately 10% overlap of adjacent irradiated surfaces, leads to the formation of a roughened area 31a with a shape similar to the one shown in FIG. 7 (d). The RMS roughness in the roughened area is around 3 nm+/−0.5 nm, measured by AFM on a 10×10 μm² scan.

A conventional surface preparation (cleaning, plasma activation) of the two substrates 1, 2 is then carried out with a view to molecular adhesion bonding.

Assembly, based on direct contact between the front faces 1a, 2a of the donor substrate 1 and the support substrate 2, produces a bonded assembly 100. The bonded assembly 100 comprises a local unbonded area 31 plumb with the roughened area 31a, within the bonding interface 3. In the plane of the bonding interface ((x,y) plane), the local unbonded area 31 has a length of around 2 mm and a width of around 100 to 250 μm.

Fracture annealing, carried out in a horizontal furnace, is applied between 200° C. and 550° C.

The local unbonded area 31 enables fracture to be initiated along the buried brittle plane 11 in a short time (around 30% of the average fracture time without the local unbonded area 31). By considering a plurality of collectively treated bonded assemblies 100, the presence of the local unbonded area 31 makes it possible to obtain less dispersed fracture times.

The SOI structure 110 obtained after separation has a non-transferred area 31b in place of the local unbonded area 31 of the bonded assembly 100, and whose size is substantially the same as that of said area 31 ([FIG. 8b]).

The surface quality 10a of the transferred thin film 10 is improved compared with an SOI structure obtained from a conventional bonded assembly, without a local unbonded area 31.

Note that a local unbonded area 31 with the particular shape disclosed in the fourth example also provides the aforementioned advantages when implemented in the bonded assemblies 100 disclosed in the first, second and third examples.

Of course, the invention is not limited to the described embodiments and variant embodiments may be envisaged without departing from the scope of the invention as defined by the claims.

1. A method of transferring a thin film to a support substrate, comprising:
providing a bonded assembly including a donor substrate and the support substrate, assembled by direct bonding at their respective front faces, along a bonding interface, the bonded assembly having a local unbonded area within this bonding interface, the donor substrate further comprising a buried brittle plane, the local unbonded area is generated solely by a roughened area, produced deliberately on at least one of the front faces of the donor and support substrates prior to assembly, the roughened area being free of topology and having a predetermined roughness with an amplitude of between 0.5 nm RMS and 60.0 nm RMS
separating along the buried brittle plane, initiated at the local unbonded area after microcrack growth in the buried brittle plane by thermal activation, the separation resulting in the transfer of a thin film from the donor substrate to the support substrate.

2. The method of claim 1, further comprising producing the roughened area by at least one laser shot generating only a surface fusion, within the first 1 to 30 nanometers, of a material making up the donor substrate and/or the support substrate, on the side of their respective front faces.

3. The method of claim 2, wherein the laser shot has a pulse duration of between 1 ns and 1000 ns.

4. The method of claim 3, wherein the laser shot is performed with a laser of wavelength 308 nm, and with an energy density of between 1.8 J/cm2 and 2.5 J/cm2.

5. The method of claim 2, wherein a laser shot of the at least one laser shot irradiates a circular surface with a diameter of less than 200 micrometers.

6. The method of claim 5, further comprising producing the roughened area by a plurality of laser shots, the adjacent circular surfaces irradiated by successive laser shots being tangential or having an overlap percentage of between 1% and 95%.

7. The method of claim 1, wherein:
the front face, whereupon the roughened area is formed, comprises monocrystalline silicon, and the predetermined roughness has an amplitude between 0.5 nm RMS and 4.0 nm RMS, or
the front face, whereupon the roughened area is formed, comprises polycrystalline silicon, and the predetermined roughness has an amplitude between 0.5 nm RMS and 5.0 nm RMS, or
the front face, whereupon the roughened area is formed, comprises silicon oxide, and the predetermined roughness has an amplitude of between 1.0 nm RMS and 60.0 nm RMS.

8. The method of claim 1, further comprising producing the roughened area on the front face of the donor substrate, prior to the formation of the buried brittle plane in the donor substrate.

9. The method of claim 8, wherein:
the donor substrate comprises a first material on its front face, and a preliminary roughened area is formed on a surface of the first material; and
thermal oxidation of the first material of the donor substrate is carried out after formation of the preliminary roughened area and before formation of the buried brittle plane, to form an insulating layer to be assembled on the support substrate in the bonded assembly, the insulating layer comprising, on its free face, the roughened area plumb with the preliminary roughened area.

10. The method of claim 1, wherein:
the support substrate comprises a first material at its front face, and a preliminary roughened area is formed on a surface of the first material; and
thermal oxidation of the first material of the support substrate is carried out after formation of the preliminary roughened area, to form an insulating layer to be assembled on the donor substrate in the bonded assembly, the insulating layer comprising, on its free face, the roughened area plumb with the preliminary roughened area.

11. The of claim 1, wherein the local unbonded area has a shape, in a plane of the bonding interface, at least a portion of the contour of the shape having a radius of curvature smaller than the radius of a circular bonding defect of the same area.

12. The method of claim 1, wherein the local unbonded area has at least one lateral dimension, in a plane of the bonding interface, of less than 300 micrometers.

13. The method of claim 1, wherein the local unbonded area is located in a central region of the bonded assembly, in a plane of the bonding interface.

14. The method of claim 1, wherein the thin film from the donor substrate is monocrystalline silicon and the support substrate comprises monocrystalline silicon, to form a stacked SOI structure.

15. The method of claim 3, wherein the laser shot has a pulse duration of between 10 ns and 500 ns.

16. The method of claim 6, wherein the plurality of laser shots comprises between two and fifteen laser shots.

17. The method of claim 7, wherein the front face, whereupon the roughened area is formed, comprises monocrystalline silicon, and the predetermined roughness has an amplitude between 1.0 nm RMS and 2.5 nm RMS.

18. The method of claim 7, wherein the front face, whereupon the roughened area is formed, comprises polycrystalline silicon, and the predetermined roughness has an amplitude between 2.0 nm RMS and 5.0 nm RMS.

19. A method of transferring a thin film to a support substrate, comprising:
forming a roughened area on at least one of a front face of a donor substrate and a front face of a support substrate, the roughened area being free of topology and having a predetermined roughness with an amplitude of between 0.5 nm RMS and 60.0 nm RMS;
forming a buried brittle plane in the donor substrate;
assembling the front face of the donor substrate with the front face of the support substrate;
bonding to front face of the donor substrate to the front face of the support substrate along a bonding interface therebetween to form a bonded assembly including the donor substrate and the support substrate, the bonded assembly having a local unbonded area within this bonding interface, the local unbonded area generated solely by the roughened area; and
heating the bonded assembly, growing microcracks in the buried brittle plane, and initiating, at the local unbonded area, fracture of the donor substrate along the buried brittle plane resulting in transfer of the thin film from the donor substrate to the support substrate.

20. The method of claim 19, further comprising producing the roughened area by at least one laser shot generating only a surface fusion of a material of the at least one of the front face of the donor substrate and the front face of the support substrate.
